(19) United States
(12) Patent Application Publication
(10) Pub. No.: US 2004/0182543 A1
(43) Pub. Date: Sep. 23, 2004

(54) Heat dissipating arrangement for portable computer

(75) Inventor: Shi-Feng Shao, Kunshan City (CN)

Correspondence Address: Raymond Y. Chan, Suite 128, 108 N. Ynez Ave., Monterey Park, CA, 91754, US

(73) Assignee: KUNSHAN ANLI PRECISE METAL CO., LTD., Kunshan City (CN)

(21) Appl. No.: 10/627,201

(22) Filed: Jul. 23, 2003

(30) Foreign Application Priority Data
Jul. 23, 2002 (CN) 02265682.0

(51) Int. Cl. H05K 7/20

(52) U.S. Cl. 165/80.3; 165/185

(57) ABSTRACT

The invention discloses a sectional arrangement of heat dissipating plates for notebook computer. The arrangement consists of a plurality of heat dissipating plates each having at least two holding means. Each holding means has a Y-shaped member having a stem and a pair of arms, and an engaging opening. In assembly, the pairs of arms of all holding means are able to be pressed inwardly through each corresponding engaging opening until each heat dissipating plate is engaged by its neighboring heat dissipating plate.

### BACKGROUND OF THE PRESENT INVENTION

1. Field of Invention

The present invention relates to a heat sink for a computer, and more particularly to a heat dissipating arrangement for portable computer, wherein the heat dissipating members are selectively to be assembled to effectively dissipate the heat from the computer.

2. Description of Related Arts

Aluminum made heat sinks are commonly used in computers since they can effectively dissipate the heat from the computer, especially the CUP. Generally, there are two types of heat sink used in computer, which are extrusion type and detachable type. FIG. 1 illustrates the extrusion type heat sink that the heat dissipating plates are integrally linked with each other to form a one piece heat sink. However, such heat sink is heavy that it is not suitable for installing into the portable computer. The detachable type heat sink is that the heat dissipating plates are detachably mounted with each other, as shown in FIG. 2, such that the heat sink is light in weight for fitting the portable computer. However, such heat sink is difficult to change its shape according to different types of the computer. In addition, such heat sink is that a process of assembling the plates into the arrangement is complex, taking time and resulting in high ratio of disqualification.

### SUMMARY OF THE PRESENT INVENTION

A main object of the present invention is to provide a heat dissipating arrangement for portable computer, wherein the heat dissipating members are selectively to be assembled to effectively dissipate the heat from the computer.

Another object of the present invention is to provide a heat dissipating arrangement for portable computer, wherein the heat dissipating members are easily assembled to form as a heat sink to dissipate the heat from the computer, thus saving producing time and lowering ratio of disqualification.

Accordingly, in order to accomplish the above objects, the present invention provides a heat dissipating arrangement for a portable computer, wherein the heat dissipating arrangement comprises at least two heat dissipating members adapted for installing into the portable computer for dissipating heat therefrom.

Each of the heat dissipating members comprises a plate body defining a heat dissipating surface and a peripheral edge, at least a heat guiding channel integrally protruded from the heating dissipating surface of the plate body, and at least an engaging arm having a narrowed root portion outwardly extended from the peripheral edge of the plate body and an engaging head portion extending from the root portion. The engaging arm of each of the heat dissipating members is adapted to fold downwardly that the engaging head portion of the engaging arm of the heat dissipating member is substantially engaged with the root portion of the engaging arm of another the dissipating member in such a manner that the heat dissipating members are communicatively mounted side by side while the heat dissipating surfaces of the heat dissipating members are spaced apart between the heat guiding channel for dissipating the heat from the portable computer.

These and other objectives, features, and advantages of the present invention will become apparent from the following detailed description, the accompanying drawings, and the appended claims.

### BRIEF DESCRIPTION OF THE DRAWINGS

FIG. 1 is a perspective view of a conventional heat sink for a portable computer.

FIG. 2 is a perspective view of another conventional heat sink for a portable computer.

FIG. 3 is a perspective view of a heat dissipating member of a heat dissipating arrangement for a portable computer according to a preferred embodiment of the present invention.

FIG. 4 is a perspective view of an engaging arm of the heat dissipating member according to the above preferred embodiment of the present invention.

FIG. 5 is a perspective view of the heat dissipating member according to the above preferred embodiment of the present invention, illustrating the folding arm being folded downwardly.

FIG. 6 is a perspective view of the heat dissipating arrangement according to the above preferred embodiment of the present invention, illustrating the heat dissipating members being mounted side by side.

FIG. 7 illustrates a plurality of the heat dissipating members being mounted to form as a heat sink for the portable computer according to the above preferred embodiment of the present invention.

FIG. 8 illustrates an alternative mode of the plate body of the heat dissipating member according to the above preferred embodiment of the present invention.

FIG. 9 illustrates an alternative mode of the heat guiding channel of the heat dissipating member according to the above preferred embodiment of the present invention.

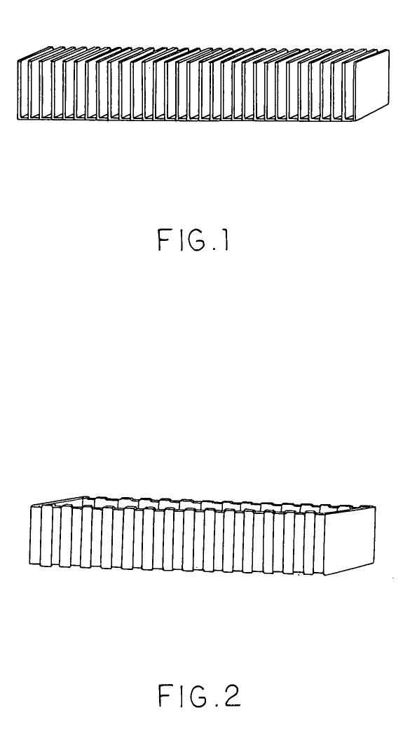

### DETAILED DESCRIPTION OF THE PREFERRED EMBODIMENT

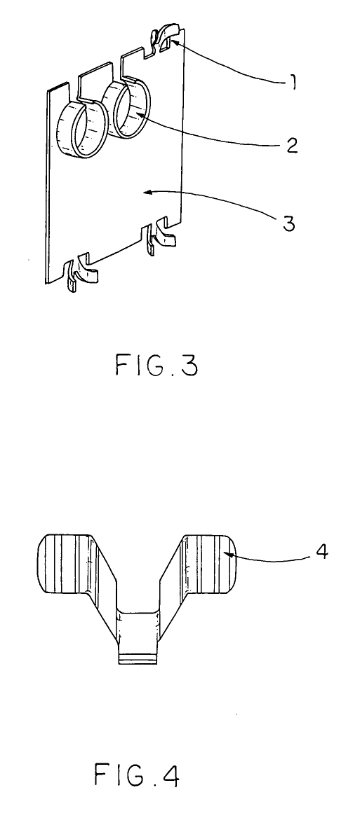

Referring to FIGS. 3 through 6, a heat dissipating arrangement for a portable computer according to a preferred embodiment of the present invention is illustrated, wherein the heat dissipating arrangement comprising at least two heat dissipating members adapted for installing into the portable computer for dissipating heat therefrom, especially from the CPU of the portable computer.

As shown in FIG. 3, each of the heat dissipating members comprises a plate body 3 defining a heat dissipating surface and a peripheral edge, at least a heat guiding channel 2 integrally protruded from the heating dissipating surface of the plate body 3, and at least an engaging arm 1 having a narrowed root portion outwardly extended from the peripheral edge of the plate body 3 and an engaging head portion extending from the root portion.

As shown in FIG. 4, the engaging arm 1 of each of the heat dissipating members is adapted to fold downwardly that the engaging head portion of the engaging arm 1 of the heat dissipating member is substantially engaged with the root portion of the engaging arm 1 of another the dissipating member in such a manner that the heat dissipating members are communicatively mounted side by side while the heat dissipating surfaces of the heat dissipating members are spaced apart between the heat guiding channel 2 for dissipating the heat from the portable computer, as shown in FIG. 6.

According to the preferred embodiment, the plate body 3 of each of the heat dissipating members is made of heat conductive material such as aluminum or copper such that the heat from the portable computer is adapted to direct to the plate body 3 so as to effectively dissipate the heat from the portable computer to outside. Accordingly, the plate body 3 is shaped and sized to a rectangular shape that fits into the portable computer.

The heat guiding channels 2 of the heat dissipating members are aligned to form an elongated heat conducting conduit for communicatively guiding the heat throughout the heat dissipating surfaces of the plate bodies 3 when the heat dissipating members are mounted with each other. As shown in FIG. 3, two heat guiding channels 2 are spacedly extended from the heating dissipating surface of each of the plate bodies 3 such that two elongated conducting conduits are spacedly formed when the heat dissipating members are mounted with each other. In addition, each of the heat guiding channels 2, having a circular shape, is positioned at an upper portion of the plate body 3 to form the circular elongated conducting conduit when the heat dissipating members are mounted with each other.

It is worth to mention that when the heat dissipating members are mounted side by side, the heat dissipating surfaces of the heat dissipating members are spaced apart to form an air compartment therebetween while the plate bodies 3 are heat-communicating with each other through the heat guiding channel 2, as shown in FIG. 6.

At least two engaging arms 1 are extended from two opposed edges of the plate body 3 respectively wherein when the plate bodies 3 are mounted side by side, the engaging arms 1 are aligned correspondingly such that when the engaging arms 1 are bent downwardly, two corresponding engaging arms 1 of the heat dissipating members are engaged with each other to substantially mount the heat dissipating members with each other.

As shown in FIG. 4, each of the engaging arms 1, having a Y-shaped, is integrally extended from the peripheral edge of the plate body 3, wherein the engaging head portion of each of the engaging arms 1 forms as two engaging wings 4 which is integrally extended from two sides of the root portion of the engaging arm 1 respectively and is adapted to engage with the root portion of the another engaging arm 1 so as to substantially mount the heat dissipating members with each other.

Accordingly, the two engaging wings 4 are symmetrically identical. Each of the engaging wings 4 is adapted to be bent 90 degrees with respect to the root portion of the engaging arms 1, as shown in FIG. 4, to engage with the root portion of the another corresponding engaging arm 1 without distorting the engaging arm 1 with respect to the plate body 3. Therefore, the two engaging wings 4 are also locked at the peripheral edge of the plate body 3 so as to lock up the two heat dissipating members in position. In other words, the root portion of the engaging arm 1 is engaged between the two engaging wings 4 of the other engaging arm 1 to mount the heat dissipating members with each other.

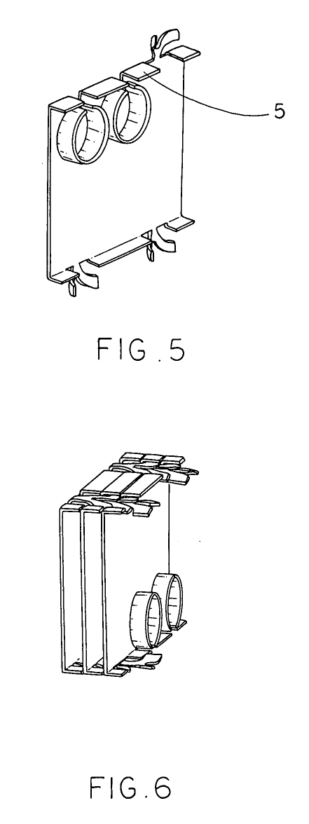

As shown in FIGS. 3 and 5, each of the heat dissipating members further comprises a folding arm 5 which is integrally extended from the peripheral edge of the plate body 3 and is arranged to downwardly fold to overlap on the folding arm 5 of the other heat dissipating member so as to enhance a contacting area between the heat dissipating members for dissipating the heat from the portable computer. Accordingly, each of the folding arms 5 is adapted to downwardly bent 90 degrees to transversely extend from the heat dissipating surface of the plate body 3 to overlap on the folding arm of another heat dissipating member.

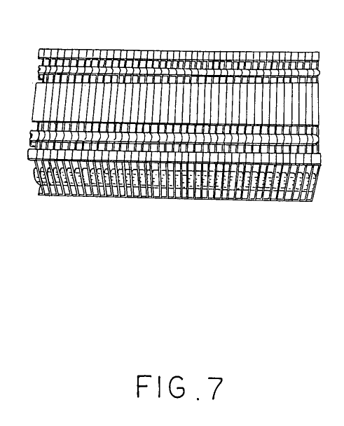

According to the preferred embodiment, the heat dissipating members are selectively assembled to function as a heat sink for the portable computer wherein numbers of heat dissipating members can be varied depending on amount of heat generation of the portable computer to substantially dissipate the heat therefrom. As shown in FIG. 7, more than thirty heat dissipating members are mounted side by side to form as a heat sink for the portable computer. In addition, the manufacturing process of the heat dissipating arrangement is inexpensive and easy that the heat dissipating member can be made individually so as to assemble the heat dissipating members together to form a heat sink.

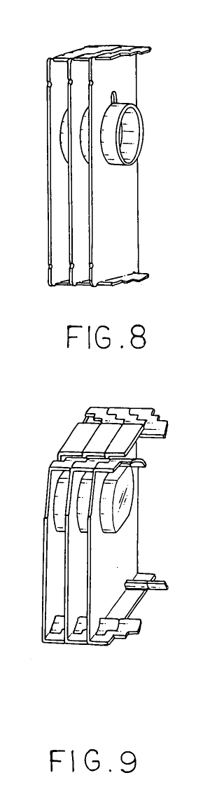

As shown in FIG. 8, the size of the heat dissipating member can be varied with respect to the size of the portable computer. The size of the heat dissipating member can be minimized to form one heat guiding channel 2 at a mid-portion of the plate body 3 and two engaging arms 1 at two opposed edges of the plate body 3 respectively.

In addition, the shape of the heat guiding channel 2 can also be altered to form a non-circular shape, such as an oval shape, that when the heat dissipating members are mounted side by side, to form a non-circular shaped heat conducting conduit, as shown in FIG. 9.

One skilled in the art will understand that the embodiment of the present invention as shown in the drawings and described above is exemplary only and not intended to be limiting.

It will thus be seen that the objects of the present invention have been fully and effectively accomplished. Its embodiments have been shown and described for the purposes of illustrating the functional and structural principles of the present invention and is subject to change without departure from such principles. Therefore, this invention includes all modifications encompassed within the spirit and scope of the following claims.

What is claimed is:

1. A heat dissipating arrangement for a portable computer, comprising at least two heat dissipating members adapted for installing into said portable computer for dissipating heat therefrom, wherein each of said heat dissipating members comprises:
a plate body defining a heat dissipating surface and a peripheral edge;
at least a heat guiding channel integrally protruded from said heating dissipating surface of said plate body; and
at least an engaging arm having a narrowed root portion outwardly extended from said peripheral edge of said plate body and an engaging head portion extending from said root portion, wherein said engaging arm of each of said heat dissipating members is adapted to fold downwardly that said engaging head portion of said engaging arm of said heat dissipating member is substantially engaged with said root portion of said engaging arm of another said dissipating member in such a manner that said heat dissipating members are communicatively mounted side by side while said heat dissipating surfaces of said heat dissipating members are spaced apart between said heat guiding channel for dissipating said heat from said portable computer.

2. The heat dissipating arrangement, as recited in claim 1, wherein each of said engaging arms, having a Y-shaped, is integrally extended from said peripheral edge of said plate body, wherein said engaging head portion of each of said engaging arms forms as two engaging wings adapted to engage with said root portion of said another engaging arm so as to substantially mount said heat dissipating members with each other.

3. The heat dissipating arrangement, as recited in claim 2, wherein said two engaging wings are symmetrically identical, wherein each of said engaging wings is bent 90 degrees with respect to said root portion of said engaging arms to engage with said root portion of another said corresponding engaging arm at said peripheral edge of said plate body.

4. The heat dissipating arrangement, as recited in claim 1, wherein each of said heat dissipating members further comprises a folding arm which is integrally extended from said peripheral edge of said plate body and is arranged to downwardly fold to overlap on said folding arm of another said heat dissipating member so as to enhance a contacting area between said heat dissipating members for dissipating said heat from said portable computer.

5. The heat dissipating arrangement, as recited in claim 2, wherein each of said heat dissipating members further comprises a folding arm which is integrally extended from said peripheral edge of said plate body and is arranged to downwardly fold to overlap on said folding arm of another said heat dissipating member so as to enhance a contacting area between said heat dissipating members for dissipating said heat from said portable computer.

6. The heat dissipating arrangement, as recited in claim 3, wherein each of said heat dissipating members further comprises a folding arm which is integrally extended from said peripheral edge of said plate body and is arranged to downwardly fold to overlap on said folding arm of another said heat dissipating member so as to enhance a contacting area between said heat dissipating members for dissipating said heat from said portable computer.

7. The heat dissipating arrangement, as recited in claim 4, wherein each of said folding arms is downwardly bent 90 degrees to transversely extended from said heat dissipating surface of said plate body to overlap on said folding arm of another said heat dissipating member.

8. The heat dissipating arrangement, as recited in claim 5, wherein each of said folding arms is downwardly bent 90 degrees to transversely extended from said heat dissipating surface of said plate body to overlap on said folding arm of another said heat dissipating member.

9. The heat dissipating arrangement, as recited in claim 6, wherein each of said folding arms is downwardly bent 90 degrees to transversely extended from said heat dissipating surface of said plate body to overlap on said folding arm of another said heat dissipating member.

10. The heat dissipating arrangement, as recited in claim 1, wherein said heat guiding channels of said heat dissipating members are aligned to form an elongated heat conducting conduit for communicatively guiding said heat throughout said heat dissipating surfaces of said plate bodies when said heat dissipating members are mounted with each other.

11. The heat dissipating arrangement, as recited in claim 3, wherein said heat guiding channels of said heat dissipating members are aligned to form an elongated heat conducting conduit for communicatively guiding said heat throughout said heat dissipating surfaces of said plate bodies when said heat dissipating members are mounted with each other.

12. The heat dissipating arrangement, as recited in claim 6, wherein said heat guiding channels of said heat dissipating members are aligned to form an elongated heat conducting conduit for communicatively guiding said heat throughout said heat dissipating surfaces of said plate bodies when said heat dissipating members are mounted with each other.

13. The heat dissipating arrangement, as recited in claim 9, wherein said heat guiding channels of said heat dissipating members are aligned to form an elongated heat conducting conduit for communicatively guiding said heat throughout said heat dissipating surfaces of said plate bodies when said heat dissipating members are mounted with each other.
